(19) United States
(12) Patent Application Publication
(10) Pub. No.: US 2024/0049362 A1
(43) Pub. Date: Feb. 8, 2024

(54) TEMPERATURE ADJUSTING MEMBER

(71) Applicant: SHINKO ELECTRIC INDUSTRIES CO., LTD., Nagano-shi (JP)

(72) Inventors: Keita Sato, Nagano-shi (JP); Shun Takagi, Nagano-shi (JP)

(21) Appl. No.: 18/364,790

(22) Filed: Aug. 3, 2023

(30) Foreign Application Priority Data
Aug. 5, 2022 (JP) 2022-125635

(51) Int. Cl. H05B 3/32

(52) U.S. Cl. CPC H05B 3/32

(57) ABSTRACT

A temperature adjusting member includes a base body, an insulator substrate including a built-in heat-generating element and an opening portion through which a part of the heat-generating element is exposed, an electric wire connected to the heat-generating element through the opening portion, and an adhesive layer bonding the base body and the insulator substrate. The base body includes a through-hole connecting to the opening portion, through which the electric wire passes. The adhesive layer has a first part between the base body and the insulator substrate, and a second part filling the through-hole.

### CROSS-REFERENCE TO RELATED APPLICATIONS

This application is based on and claims the benefit of priority from prior Japanese patent application No. 2022-125635 filed on Aug. 5, 2022, the entire contents of which are incorporated herein by reference.

### TECHNICAL FIELD

The present disclosure relates to a temperature adjusting member.

### BACKGROUND ART

In a temperature adjusting member that adjusts a temperature of a substrate such as a wafer, an insulator substrate and a base body are bonded using an adhesive. The insulator substrate has a built-in heat-generating element for heating the substrate, and the insulator substrate is formed with an opening portion connecting to the heat-generating element. An electric wire connected to the heat-generating element is provided in the opening portion. In addition, the base body is formed with a through-hole connecting to the opening portion of the heat-generating element, and the electric wire passes through the through-hole.

### CITATION LIST

### Patent Literature

Patent Literature 1: JP2003-133401A

Patent Literature 2: JP2019-156648A

Patent Literature 3: Japanese Patent No. 3993408

In the temperature adjusting member of the related art, a difference may occur in temperature distribution on a surface (hereinafter, also referred to as “attachment surface”) in use, to which a target object of temperature adjustment is attached, among a plurality of temperature adjusting members. In addition, the temperature distribution on the attachment surface in use may deviate from a predetermined range.

### SUMMARY OF INVENTION

An object of the present disclosure is to provide a temperature adjusting member capable of improving stability of a temperature distribution on a surface to which a target object of temperature adjustment is attached.

A temperature adjusting member includes a base body, an insulator substrate including a built-in heat-generating element and an opening portion through which a part of the heat-generating element is exposed, an electric wire connected to the heat-generating element through the opening portion, and an adhesive layer bonding the base body and the insulator substrate. The base body includes a through-hole connecting to the opening portion, through which the electric wire passes. The adhesive layer has a first part between the base body and the insulator substrate, and a second part filling the through-hole.

According to the present disclosure, it is possible to improve stability of the temperature distribution on the surface to which the target object of temperature adjustment is attached.

### BRIEF DESCRIPTION OF DRAWINGS

FIG. 1 is a cross-sectional view exemplifying a temperature adjusting member according to an embodiment.

FIG. 2 is a flowchart exemplifying a manufacturing method of the temperature adjusting member according to the embodiment.

FIG. 3 is a cross-sectional view exemplifying a manufacturing method of the temperature adjusting member according to the embodiment.

FIG. 4 is a cross-sectional view exemplifying the manufacturing method of the temperature adjusting member according to the embodiment.

FIG. 5 is a cross-sectional view exemplifying the manufacturing method of the temperature adjusting member according to the embodiment.

FIG. 6 is a cross-sectional view exemplifying the manufacturing method of the temperature adjusting member according to the embodiment.

FIG. 7 is a cross-sectional view exemplifying the manufacturing method of the temperature adjusting member according to the embodiment.

FIG. 8 is a cross-sectional view exemplifying the manufacturing method of the temperature adjusting member according to the embodiment.

FIG. 9 shows a simulation result.

### DESCRIPTION OF EMBODIMENTS

The present inventors conducted intensive studies to find out a cause of the difference in temperature distribution on the attachment surface in use in the temperature adjusting member of the related art. As a result, it was found that the adhesive flows into the through-hole of the base body when bonding the insulator substrate and the base body but an inflow amount of the adhesive is not uniform. For example, there is a case where an amount of the adhesive that has flowed into the through-hole is different among a plurality of temperature adjusting members. In addition, when a plurality of through-holes are provided in one temperature adjusting member, an inflow amount of the adhesive may be different among the plurality of through-holes. For example, even when a thickness of the base body is about 40 mm and the temperature adjusting member is manufactured under the same conditions, the adhesive may flow from a surface (lower surface) of the base body on an opposite side to the insulator substrate up to a position of about 5 mm or about 30 mm. Such a difference in the inflow amount of the adhesive leads to a difference in thermal conductivity, resulting in a difference in temperature distribution on the attachment surface in use.

Even when the adhesive having flowed into the through-hole is removed, it is difficult to completely remove the adhesive in the through-hole while leaving the adhesive between the base body and the insulator substrate, and therefore, the adhesive inevitably remains in the through-hole. It is difficult to stabilize an amount of the adhesive that inevitably remains, and therefore, a difference in the thermal conductivity occurs.

The present disclosure has been made based on these findings, and improves the stability of the temperature distribution on the attachment surface even when there is a difference in the inflow amount of the adhesive.

Hereinafter, embodiments of the present disclosure will be described with reference to the accompanying drawings. Note that, in the specification and drawings, the constitutional elements having substantially the same functional configurations are denoted with the same reference signs, and the overlapping descriptions may be omitted.

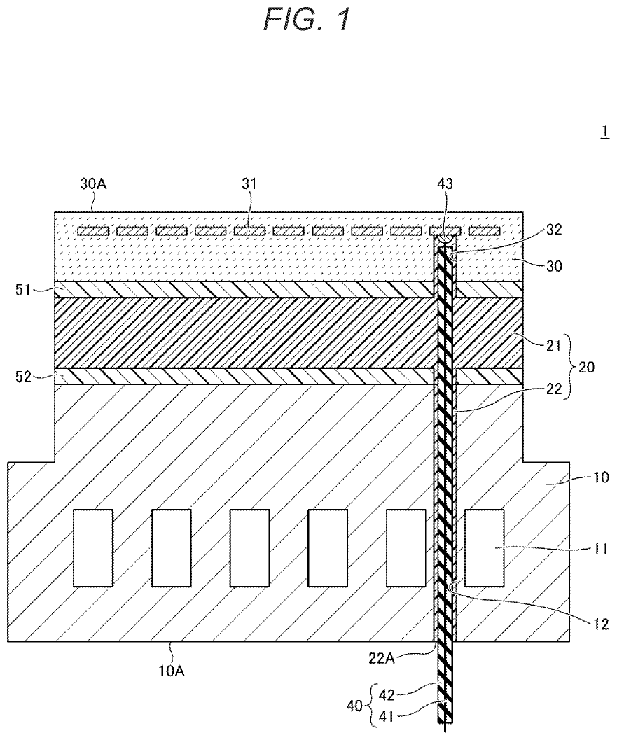

The present embodiment relates to a temperature adjusting member. FIG. 1 is a cross-sectional view exemplifying a temperature adjusting member according to an embodiment.

As shown in FIG. 1, a temperature adjusting member 1 according to the embodiment includes, as main constitutional elements, a base body 10, a second adhesion auxiliary layer 52, an adhesive layer 20, a first adhesion auxiliary layer 51, an insulator substrate 30, and an electric wire 40.

Note that, in the present embodiment, for convenience sake, a side on which the insulator substrate 30 is located when seen from the base body 10 is referred to as an upper side or one side, and a side on which the base body 10 is located when seen from the insulator substrate 30 is referred to as a lower side or the other side. In addition, a surface of each part on the insulator substrate 30-side is referred to as an upper surface or one surface, and a surface on the base body 10-side is referred to as a lower surface or the other surface.

The insulator substrate 30 has, for example, a disk shape. A target object whose temperature is to be adjusted is attached to an upper surface 30A of the insulator substrate 30. The insulator substrate 30 includes an insulator such as a ceramic sintered body or glass. Examples of a material of the ceramic sintered body may include aluminum oxide (Al₂O₃) and aluminum nitride (AlN). For example, a thickness of the insulator substrate 30 is, for example, about 1 mm to 10 mm, and a relative permittivity of the insulator substrate 30 is, for example, about 9 to 10 at a frequency of 1 kHz. A conductive pattern 31 functioning as a heat-generating element is built in the insulator substrate 30. The conductive pattern 31 includes a sintered body of metal particles or a metal foil. When current is caused to flow through the conductive pattern 31, the conductive pattern 31 generates heat. When the conductive pattern 31 generates heat, a target object such as a substrate attached to the upper surface 30A of the insulator substrate 30 can be heated. A position of the conductive pattern 31 in the insulator substrate 30 is not particularly limited. One or more conductive patterns 31 may be built in the insulator substrate 30. The insulator substrate 30 may also include an electrostatic adsorption pattern that functions as an electrostatic electrode for electrostatically adsorbing an object, or may also include a pattern that attracts plasma by applying a high-frequency voltage. The insulator substrate 30 may also include various other patterns. When the insulator substrate 30 includes an electrostatic adsorption pattern, the temperature adjusting member 1 can be used as an electrostatic chuck.

An opening portion 32 through which a part of the conductive pattern 31 is exposed is formed in the insulator substrate 30. The electric wire 40 has a conductor 41 and an insulating sheath 42. The conductor 41 is made of a material with low electrical resistivity such as metal. The conductor 41 has, for example, a solid wire or a stranded wire. An outer circumferential surface of conductor 41 is covered by the sheath 42. One end portion of the conductor 41 is connected to the conductive pattern 31 by a conductive bonding material 43. The conductive bonding material 43 is, for example, brazing metal, solder or a conductive adhesive. In addition to the conductive bonding material 43, an electrode member may also be included between the conductor 41 and the conductive pattern 31.

The base body 10 has, for example, a disk shape. The base body 10 includes metal such as aluminum or a ceramic sintered body. A thickness of the base body 10 is, for example, about 20 mm to 50 mm. The base body 10 is formed with a flow path 11 through which a cooling medium flows. A location of the flow path 11 for the cooling medium in the base body 10 is not particularly limited. One or more flow passages 11 may be formed in the base body 10. By circulating the cooling medium through the flow path 11 to cool the base body 10, a target object such as a substrate attached to the upper surface 30A of the insulator substrate 30 can be cooled. The base body 10 is formed with a through-hole 12 connecting to the opening portion 32, through which the electric wire 40 passes.

The adhesive layer 20 bonds the base body 10 and the insulator substrate 30. The adhesive layer 20 includes, for example, a high molecular compound. The adhesive layer 20 may be composed of a high molecular compound. Examples of a material of the adhesive layer 20 may include a silicone resin, an epoxy resin, an acrylic resin and a polyimide resin. A composite material thereof may also be used for the adhesive layer 20. In addition, the adhesive layer 20 may include a filler. Examples of a material of the filler may include silica, alumina and aluminum nitride.

The adhesive layer 20 has a first part 21 between the base body 10 and the insulator substrate 30 and a second part 22 that fills the through-hole 12. For example, a lower surface 10A of the base body 10 and a lower surface 22A of the second part 22 are flush with each other. Note that, in the present disclosure, a state in which the through-hole 12 is filled by the second part 22 does not mean only a state in which the through-hole 12 is entirely filled by the second part 22 without excess or deficiency. A state in which a volume of the second part 22 in the through-hole 12 is 90% or greater and less than 100% of a volume (hereinafter, also referred to as ‘substantial volume of the through-hole 12’) of the through-hole 12 excluding a volume of the electric wire 40 in the through-hole 12 is also included in the state in which the through-hole 12 is filled by the second part 22. In addition, a state in which the volume of the second part 22 is within a range of greater than 100% and equal to or less than 110% of the substantial volume of the through-hole 12 and a portion of the second part 22 protrudes from the through-hole 12 is also included in the state in which the through-hole 12 is filled by the second part 22. Preferably, the volume of the second part 22 is 95% or greater and 105% or less of the substantial volume of the through-hole 12.

The first adhesion auxiliary layer 51 is located between the first part 21 of the adhesive layer 20 and the insulator substrate 30. The first adhesion auxiliary layer 51 includes, for example, a surface modifier or a coupling agent. The surface modifier makes it easy for a surface of the insulator substrate 30 to interact with an adhesive constituting adhesive layer 20. The first adhesion auxiliary layer 51 may also include a resin. The first adhesion auxiliary layer 51 increases adhesion strength between the insulator substrate 30 and the base body 10.

The second adhesion auxiliary layer 52 is located between the first part 21 of the adhesive layer 20 and the base body 10. The second adhesion auxiliary layer 52 includes, for example, a surface modifier or a coupling agent. The surface modifier makes it easy for a surface of the base body 10 to interact with the adhesive constituting the adhesive layer 20. The second adhesion auxiliary layer 52 may also include a resin. The second adhesion auxiliary layer 52 increases the adhesion strength between the insulator substrate 30 and the base body 10.

The temperature adjusting member 1 has such a configuration.

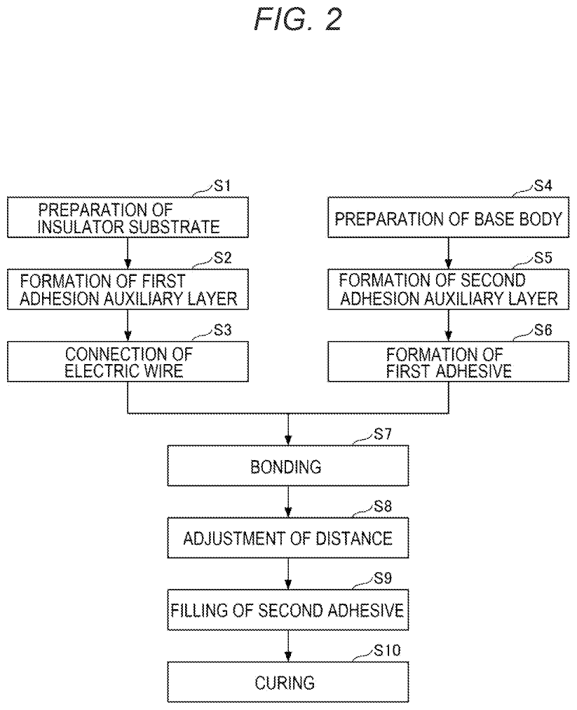

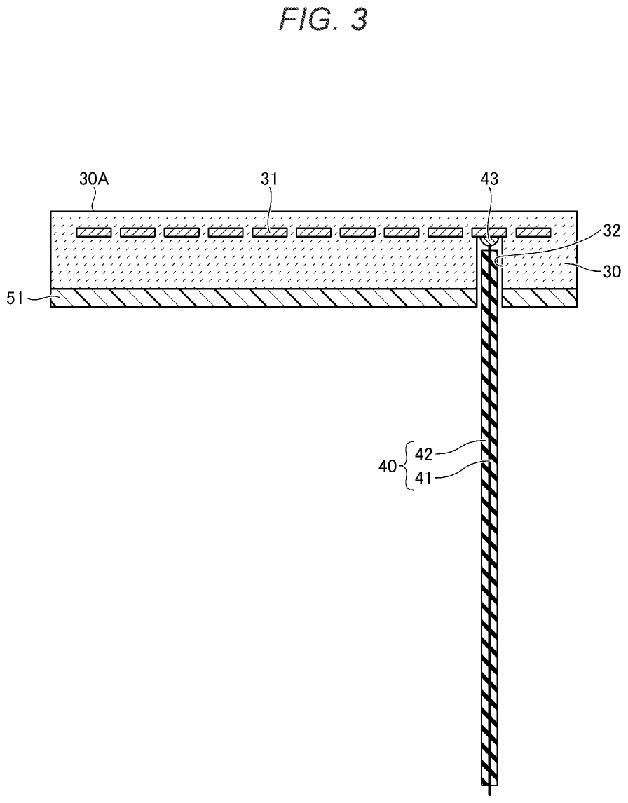

Next, a manufacturing method of the temperature adjusting member 1 according to the embodiment will be described. FIG. 2 is a flowchart exemplifying a manufacturing method of the temperature adjusting member 1 according to the embodiment. FIGS. 3 to 8 are cross-sectional views exemplifying the manufacturing method of the temperature adjusting member 1 according to the embodiment.

First, as shown in FIG. 3, an insulator substrate 30 is prepared in which a conductive pattern 31 functioning as a heat-generating element is built and an opening portion 32 through which a part of the conductive pattern 31 is exposed is formed (step S1). Next, a first adhesion auxiliary layer 51 is formed on a surface of the insulator substrate 30 where the opening portion 32 is formed (step S2). Next, an electric wire 40 is connected to the conductive pattern 31 through the opening portion 32 (step S3). The electric wire 40 is connected to the conductive pattern 31 by using, for example, a conductive bonding material 43. Note that, after connecting the electric wire 40 to the conductive pattern 31, the first adhesion auxiliary layer 51 may also be formed.

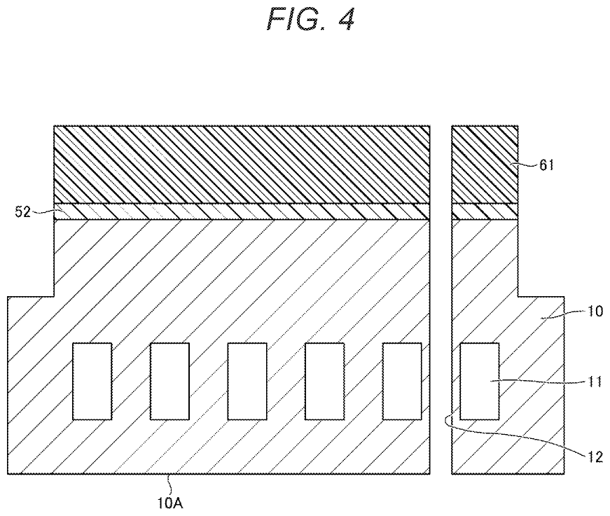

Further, separately, as shown in FIG. 4, a base body 10 formed with a through-hole 12 connecting to the opening portion 32, through which the electric wire 40 passes, is prepared (step S4). Next, a second adhesion auxiliary layer 52 is formed on a surface of the base body 10, which connects to the insulator substrate 30 (step S5). Next, a liquid first adhesive 61 is provided on the second adhesion auxiliary layer 52 (step S6). An amount of the first adhesive 61 is made larger than a volume of a space between the base body 10 and the insulator substrate 30 when a distance between the base body 10 and the insulator substrate 30 is a predetermined distance.

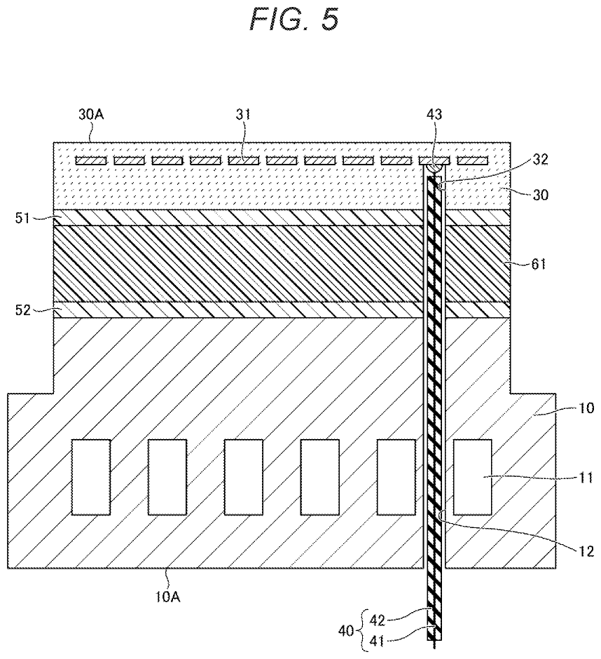

Thereafter, as shown in FIG. 5, the base body 10 and the insulator substrate 30 are bonded with the first adhesive 61 interposed therebetween so that the electric wire 40 passes through the through-hole 12 (step S7).

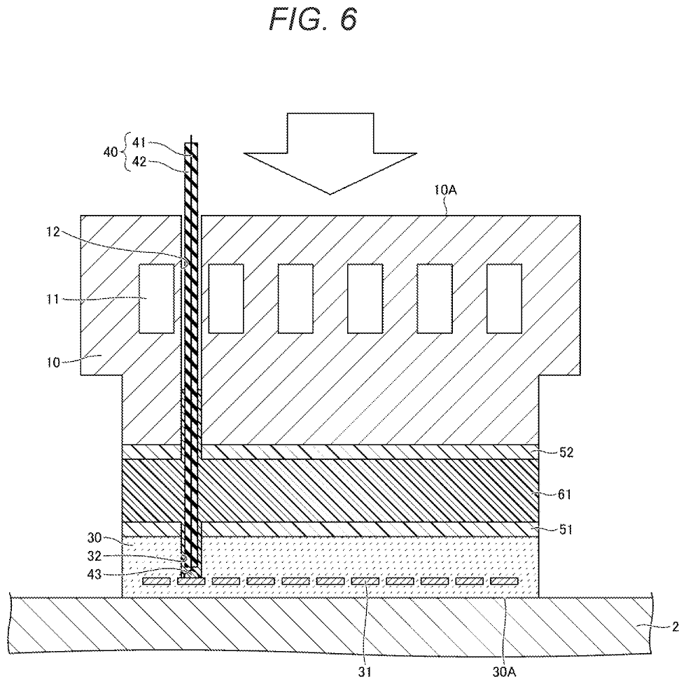

Next, as shown in FIG. 6, by pressing the base body 10 against the insulator substrate 30, the distance between the base body 10 and the insulator substrate 30 is set to the predetermined distance. That is, the distance between the base body 10 and the insulator substrate 30 is adjusted (step S8). At this time, a part of the first adhesive 61 stays between the base body 10 and the insulator substrate 30, and the other part flows out through the through-hole 12. Note that, when pressing the base body 10 against the insulator substrate 30, for example, a laminated body including the base body 10 and the insulator substrate 30 is placed on a support member 3 such as a surface plate or the like so that a surface becoming an upper surface of the insulator substrate 30 faces vertically downward, and the base body 10 is pressed toward the insulator substrate 30 from a vertically upward position.

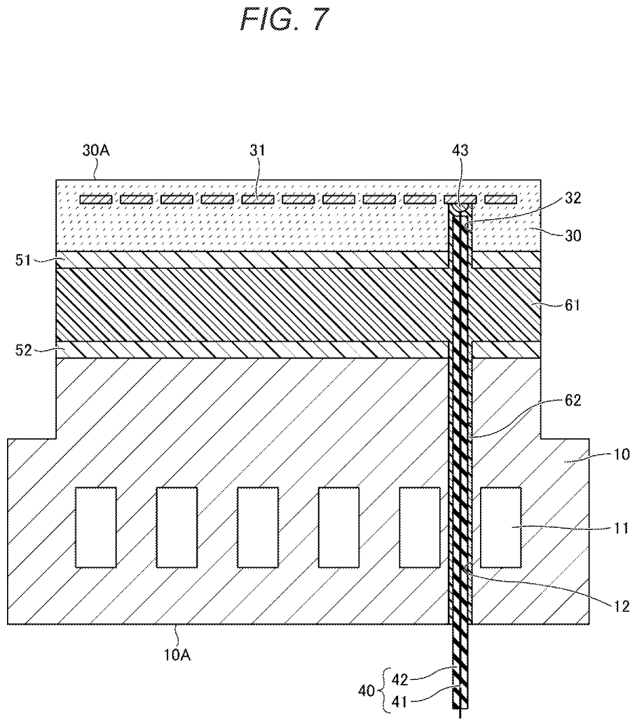

Next, as shown in FIG. 7, a second adhesive 62 is filled in the through-hole 12 (step S9). For example, the second adhesive 62 is the same type of adhesive as the first adhesive 61. When filling the second adhesive 62, for example, a syringe is filled with the second adhesive 62, and the second adhesive 62 is injected into the through-hole 12 through a needle. Note that, when the through-hole 12 is filled with the first adhesive 61, the filling of the second adhesive 62 may be omitted.

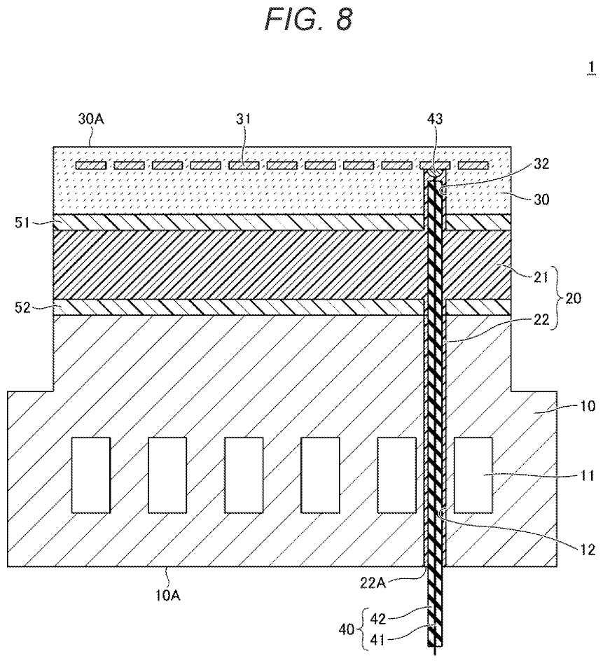

Next, as shown in FIG. 8, the first adhesive 61 and the second adhesive 62 are cured (step S10). The first adhesive 61 and the second adhesive 62 are cured using, for example, a heating furnace. As a result, an adhesive layer 20 having a first part 21 and a second part 22 is formed. If the second part 22 protrudes excessively from the through-hole 12, the protruding portion is removed so that a lower surface 22A of the second part 22 is flush with a lower surface 10A of the base body 10. However, the lower surface 22A does not have to be completely flush with the lower surface 10A, and a volume of the second part 22 may be 90% or greater and 110% or less of the substantial volume of the through-hole 12.

In this way, the temperature adjusting member 1 according to the embodiment can be manufactured.

In the temperature adjusting member 1, the second part 22 of the adhesive layer 20 fills the through-hole 12 of the base body 10. For this reason, an amount of the adhesive layer 20 in the through-hole 12 is stable, and the thermal conductivity in the through-hole 12 is stable. Therefore, the stability of the temperature distribution on the upper surface 30A of the insulator substrate 30, which is the surface to which a target object is attached, can be improved.

In addition, since the thermal conductivity in the through-hole 12 is stable, when changing a design of the conductive pattern 31 or the flow path 11, it is easy to simulate a temperature distribution after the design change.

Note that the temperature adjusting member 1 may not include one or both of the first adhesion auxiliary layer 51 and the second adhesion auxiliary layer 52.

The base body 10, the second adhesion auxiliary layer 52, the adhesive layer 20, the first adhesion auxiliary layer 51, and the insulator substrate 30 may be formed with a flow path through which a gas to be ejected to a target object, for example, an inert gas flows.

Here, a simulation performed by the present inventors will be described. In this simulation, the change in the temperature distribution on the upper surface 30A of the insulator substrate 30 when the amount of the adhesive layer 20 in the through-hole 12 was changed was calculated from the temperature adjusting member 1 according to the embodiment. Specifically, the thickness of the base body 10 was about 40 mm, the thickness of the insulator substrate 30 was about 7.0 mm, and the thickness of the first part 21 of the adhesive layer 20 was about 0.2 mm. The amount of the adhesive layer 20 in the through-hole 12 was changed under 5 conditions, and was expressed as the distance between the lower surface 22A of the second part 22 and the lower surface 10A of the base body 10. In addition, the temperature of the refrigerant flowing through the flow path 11 was 20° C.

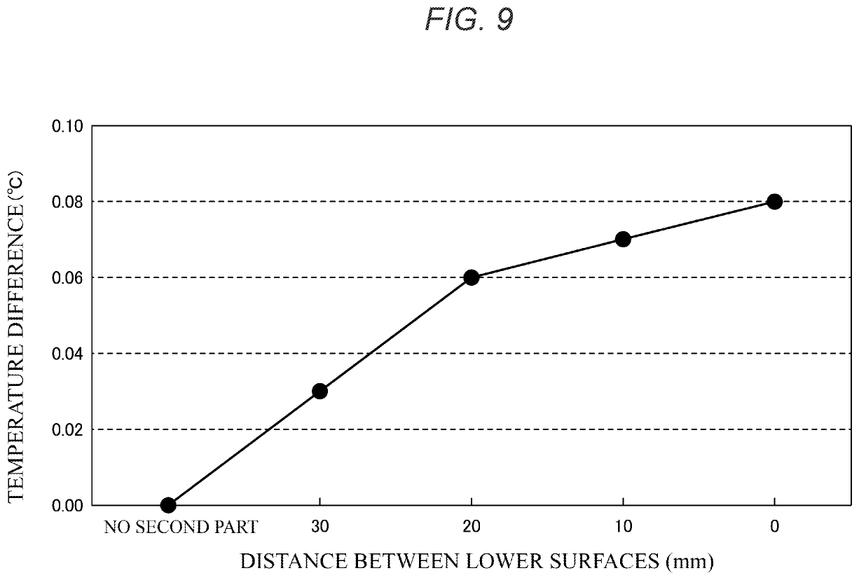

Then, for each condition of the amount of the adhesive layer 20 in the through-hole 12, the temperature at the position in the upper surface 30A closest to the through-hole 12 was calculated when the current flowing through the conductive pattern 31 was adjusted so that the average temperature of the upper surface 30A of the insulator substrate 30 was 60° C. A result thereof is shown in FIG. 9. FIG. 9 shows a simulation result. The horizontal axis in FIG. 9 represents the distance between the lower surface 22A and the lower surface 10A. The vertical axis in FIG. 9 indicates how low (temperature difference) the temperature under the other conditions is based on the temperature under the condition that the adhesive layer 20 does not exist in the through-hole 12.

As shown in FIG. 9, the temperature at the position in the upper surface 30A closest to the through-hole 12 is different according to the amount of the adhesive layer 20 in the through-hole 12. In addition, the smaller the amount of the adhesive layer 20 in the through-hole 12 is, the greater the change in temperature difference relative to the change in the amount of the adhesive layer 20 in the through-hole 12 is. For example, when the distance between the lower surface 22A and the lower surface 10A changes in the range of 10 mm to 30 mm, the temperature difference is 0.04° C., but when the distance changes in the range of 0 mm to 10 mm, the temperature difference is 0.01° C.

This indicates that since the through-hole 12 is filled by the second part 22, the non-uniformity of temperature at the position in the upper surface 30A closest to the through-hole 12 is suppressed and the stability of the temperature distribution on the upper surface 30A can be improved. In addition, it can be said that, when the volume of the second part 22 is 90% or greater and 110% or less of the substantial volume of the through-hole 12, a stable temperature distribution is obtained even if the lower surface 22A and the lower surface 10A are not completely flush with each other.

Although the preferred embodiments and the like have been described in detail, the present invention is not limited to the above-described embodiments and the like, and a variety of changes and replacements can be made for the above-described embodiments and the like without departing from the scope defined in the claims.

This disclosure further encompasses various exemplary embodiments, for example, described below.
[1] A method of manufacturing a temperature adjusting member comprising:
preparing an insulator substrate including a built-in heat-generating element and an opening portion through which a part of the heat-generating element is exposed;
connecting an electric wire to the heat-generating element through the opening portion;
preparing a base body including a through-hole connecting to the opening portion, through which the electric wire passes;
bonding the base body and the insulator substrate with a first adhesive;
filling the through-hole with a second adhesive; and
   curing the first adhesive and the second adhesive.

What is claimed is:

1. A temperature adjusting member comprising: a base body;
an insulator substrate including a built-in heat-generating element and an opening portion through which a part of the heat-generating element is exposed;
an electric wire connected to the heat-generating element through the opening portion; and
an adhesive layer bonding the base body and the insulator substrate,
wherein the base body includes a through-hole connecting to the opening portion, through which the electric wire passes, and
wherein the adhesive layer has:
a first part between the base body and the insulator substrate, and
a second part filling the through-hole.

2. The temperature adjusting member according to claim 1, wherein the insulator substrate comprises a ceramic sintered body.

3. The temperature adjusting member according to claim 1, further comprising:
a first adhesion auxiliary layer located between the first part and the insulator substrate.

4. The temperature adjusting member according to claim 1, further comprising:
a second adhesion auxiliary layer located between the first part and the base body.

5. The temperature adjusting member according to claim 1, wherein the base body has a flow path through which refrigerant is to flow.

6. The temperature adjusting member according to claim 1, wherein a volume of the second part in the through-hole is 90% or greater and equal to or less than 110% of a volume of the through-hole excluding a volume of the electric wire in the through-hole.
